(19) United States
(12) Patent Application Publication
(10) Pub. No.: US 2004/0245555 A1
(43) Pub. Date: Dec. 9, 2004

(54) Semiconductor storage device

(75) Inventor: Takehiro Ueda, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 10/854,307

(22) Filed: May 27, 2004

(30) Foreign Application Priority Data
Jun. 5, 2003 (JP) 2003-161150

(51) Int. Cl. G11C 15/00

(52) U.S. Cl. 257/296

(57) ABSTRACT

The semiconductor storage device of the present invention is provided with a first cell unit including a first memory cell selection transistor, a first and a second compare transistors and a first capacitor; and a second cell unit including a second memory cell selection transistor, a third and a fourth compare transistors and a second capacitor; the cell units being disposed side by side along a boundary to constitute a memory cell, in which the second compare transistor controlled by a first compare line is connected to a match line, and the fourth compare transistor controlled by a second compare line is connected to a ground line.

This application is based on Japanese patent applications NO.2003-161150, the content of which is incorporated hereinto by reference.

### BACKGROUND OF THE INVENTION

1. Field of the Invention

The present invention relates to a semiconductor storage device, and more particularly to a semiconductor storage device having a search function for finding if a data identical to a comparative data is stored or not when the comparative data is input.

2. Description of the Related Art

Semiconductor integrated circuit devices are broadly divided into memory devices (semiconductor storage devices) and logic devices, out of which the former have been achieving more prominent development thanks to the recent progress of semiconductor manufacturing technique. Referring to the memory devices, which can be classified into DRAM (Dynamic Random Access Memory) and SRAM (Static Random Access Memory), most of them are constituted of MOS (Metal Oxide Semiconductor) transistors. Between the DRAM and the SRAM, the DRAM has an advantage of a smaller memory cell size than that of the SRAM, because a memory cell of the DRAM can be constituted of a fewer number of MOS transistors. Further, lately a so-called embedded DRAM, provided with a DRAM and a logic device disposed in combination on a single chip, has come to be popularly used.

A DRAM is provided with memory cells, each including a memory cell selection transistor constituted of an MOS transistor that performs a switching operation and a capacitor connected to the memory cell selection transistor, for storing binary information represented by either “0” or “1” according to a charge status in the capacitor. Therefore by integrating a certain number of memory cells, a DRAM having a desired capacity can be constituted. For writing (storing) or reading information in or out of such DRAM, an address has to be designated in advance, such that the information is written in or read out of a memory cell located at the designated address.

Further to the above, a semiconductor storage device called CAM (Content Addressable Memory) is currently available. The CAM has a search function to find if there is a data identical to a comparative data therein when the comparative data is supplied. With the search function, the CAM can be utilized for instantaneously retrieving desired information from a network, for example. With the CAM, a searching time can be significantly shortened when compared with a conventional sequential search method.

While the CAM may be constituted of either a DRAM or an SRAM, it is more advantageous to employ a DRAM because of a merit of a smaller memory cell size. There has been disclosed in U.S. Pat. No. 6,320,777 a CAM constituted of a DRAM. The CAM disclosed therein is shown in FIG. 15. Here, the CAM includes a plurality of memory cells MC. Each of the memory cells MC includes a pair of transistors consisting of a first memory cell selection transistor T1 and a second memory cell selection transistor T2 controlled by a word line WL; a pair of transistors consisting of a first compare transistor T3 and a second compare transistor T4 respectively connected in series between a ground line GL and a match line ML; a pair of transistors consisting of a third compare transistor T5 and a fourth compare transistor T6; and a pair of capacitors consisting of a first capacitor C1 and a second capacitor C2 respectively connected in series between an upper electrode and a contact between a terminal of the first memory cell selection transistor T1 and the second memory cell selection transistor T2 and a gate of the first compare transistor T3 and the third compare transistor T5. The other terminal of the first memory cell selection transistor T1 and that of the second memory cell selection transistor T2 are respectively connected to a first bit line BL+ and a second bit line BL−, and the second compare transistor T4 and the fourth compare transistor T6 are respectively controlled by a first compare line CMP− and a second compare line CMP+.

It means that a first cell unit U1 constituted of the first memory cell selection transistor T1, the first compare transistor T3, the second compare transistor T4 and the first capacitor C1, and a second cell unit U2 constituted of the second memory cell selection transistor T2, the third compare transistor T5, the fourth compare transistor T6 and the second capacitor C2, are symmetrically configurated. Also, the first compare transistor T3 and the third compare transistor T5 respectively connected to the capacitor C1 and the capacitor C2 in the cell unit U1 and the cell unit U2 are both connected to the ground line GL, while the second compare transistor T4 and the fourth compare transistor T6 respectively controlled by the first compare line CMP− and the second compare line CMP+ are both connected to the match line ML. It is also to be noted that the transistors T1 to T6 are constituted of an MOS transistor which, as already mentioned, has a higher integration level.

The CAM constituted as shown in FIG. 15 has logical values shown in Table 1. The search is performed through comparison of a comparative data which is input to the first compare line CMP− and the second compare line CMP+ with data stored in advance in the pair of capacitor C1 and the capacitor C2, with the match line ML precharged by a precharge source PC in advance.

TABLE 1

| | D | D | S | S | SD | |
|---|---|---|---|---|---|---|
| STATUS | BL+ | BL− | CMP+ | CMP− | ML | |
| 1 | 0 | 0 | 0 | 1 | NC | Always Match |
| 2 | 0 | 0 | 1 | 0 | NC | Always Match |
| 3 | 0 | 1 | 0 | 1 | NC | Match |
| 4 | 0 | 1 | 1 | 0 | 0 | Fail |
| 5 | 1 | 0 | 0 | 1 | 0 | Fail |
| 6 | 1 | 0 | 1 | 0 | NC | Match |

Referring to the logical values in the Table 1, the first bit line BL+ and the second bit line BL− are both “0” in status 1 and 2; therefore the first compare transistor T3 and the third compare transistor T5 are switched off since charge is not accumulated in either of the capacitor C1 or the capacitor C2. Accordingly, the match line ML remains precharged (no connection state=NC) irrespective of the comparative data input to the first compare line CMP− and the second compare line CMP+. Therefore “Always Match” is output as a search result.

In the status 3, charge is accumulated in the capacitor C2 because the second bit line BL− is “1”. Therefore, the third compare transistor T5 is switched on. By contrast, since a comparative data input to the second compare line CMP+ is “0”, the fourth compare transistor T6 is swiched off. Also, since a comparative data input to the first compare line CMP− is “1”, the second compare transistor T4 is switched on. By contrast, since the first bit line BL+ is “0”, the first compare transistor T3 is swiched off. Consequently, the match line ML remains in the NC state and “Match” is output as a search result.

A similar operation is performed in the status 6. In this status, since the first bit line BL+ is “1”, charge is accumulated in the capacitor C1. Therefore, the first compare transistor T3 is switched on. By contrast, since a comparative data input to the first compare line CMP− is “0”, the second compare transistor T4 is switched off. Also, since a comparative data input to the second compare line CMP+ is “1” the fourth compare transistor T6 is switched on, while since the second bit line BL− is “0”, the third compare transistor T5 is switched off. Consequently, the match line ML remains in the NC state and “Match” is output as a search result.

On the other hand, referring to the status 4, since the second bit line BL− is “1”, charge is accumulated in the capacitor C2. Therefore, the third compare transistor T5 is switched on. Also, since a comparative data input to the second compare line CMP+ is “1”, the fourth compare transistor T6 is switched on. Accordingly the match line ML becomes electrically connected with the ground line GL, i.e. no longer in the NC state, and “Fail” is output as a search result.

A similar operation is performed in the status 5. Since the first bit line BL+ is “1”, charge is accumulated in the capacitor C1. Therefore, the first compare transistor T3 is switched on. Also, since a comparative data input to the first compare line CMP− is “1”, the second compare transistor T4 is switched on. Accordingly the match line ML becomes electrically connected with the ground line GL, i.e. no longer in the NC state, and “Fail” is output as a search result.

Meanwhile, statuses where the first bit line BL+ and the second bit line BL− are both “1”, the search result will be “Always NOT Match, or Fail” either by inputting a comparative data “1” to the first compare line CMP− or by inputting a comparative data “1” to the second compare line CMP+. Therefore, such statuses are excluded.

Accordingly, a CAM provided with the foregoing search function is usually utilized in a form of a Ternary CAM designed to distinguish the three states of “Always Match”, “Match” and “Fail”.

FIG. 16 is a plan view showing a conventional CAM manufactured (integrated) in accordance with the circuit configuration shown in FIG. 15. FIG. 17 is a cross-sectional view taken along the line E-E of FIG. 16. FIG. 18 is a cross-sectional view taken along the line F-F of FIG. 16. FIG. 19 is a cross-sectional view taken along the line G-G of FIG. 16.

As shown in FIG. 16, a memory cell MC of the CAM consists of a combination of the first cell unit U1 and the second cell unit U2 of FIG. 15 disposed vertically adjacent to each other. In this configuration, the second cell unit U2 disposed below the first cell unit U1 is identical with the first cell unit U1 folded back with respect to a boundary I-I. In other words, the first cell unit U1 and the second cell unit U2 are symmetrically disposed with respect to a plane orthogonally intersecting the drawing through the boundary I-I (i.e. the boundary I-I is the axis of symmetry).

The first bit line BL+ is connected to a diffusion layer 101A constituting a source (or drain) region of the first memory cell selection transistor T1 via a contact 102A. The first bit line BL+ is laterally extending along the outskirts of the capacitor C1 formed in an upper layer of the first bit line BL+.

Also, the diffusion layer 101A constituting a drain (or source) region of the first memory cell selection transistor T1 is connected to a lower electrode 104A, cylindrically shaped for example, of the capacitor C1 via a contact 103A. The lower electrode 104A is also connected to a gate line 110A of the first compare transistor T3 via a contact 107A connected to the diffusion layer 101A, an interconnect 108A and a contact 109A. An upper electrode 106 confronting the lower electrode 104A of the capacitor C1 via a capacitance dielectric film 105 serves as an electrode to be used in common for all the memory cells. Further, a diffusion layer 112 constituting a source (or drain) region of the first compare transistor T3 and the second compare transistor T4 is provided in a vertical direction of the drawing. A gate line 110A and a gate line ll1A of the first compare transistor T3 and the second compare transistor T4 respectively are disposed on an upper layer of the diffusion layer 112.

Likewise, the second bit line BL− of the second cell unit U2 is connected to a diffusion layer 101B constituting a source (or drain) region of the memory cell selection transistor T2 via a contact 102B. The second bit line BL− is laterally extending along the outskirts of the capacitor C2 formed in an upper layer of the second bit line BL−.

Also, the diffusion layer 101B constituting a drain (or source) region of the second memory cell selection transistor T2 is connected to a lower electrode 104B, cylindrically shaped for example, of the capacitor C2 via a contact 103B. The lower electrode 104B is also connected to a gate line 110B of the third compare transistor T5 via a contact 107B connected to the diffusion layer 101B, an interconnect 108B and a contact 109B. The upper electrode 106 confronting the lower electrode 104B of the capacitor C2 via the capacitance dielectric film 105 serves as an electrode to be used in common for all the memory cells.

Also, a gate line 110B and a gate line 111B of the third compare transistor T5 and the fourth compare transistor T6 respectively are disposed in an upper layer of the diffusion layer 112. Further, a word line WL is provided in a vertical direction of the drawing, and a contact 113A and a contact 113B connected to the ground line GL, as well as a contact 114 connected to the match line ML are disposed on the diffusion layer 112. The CAM is constituted by disposing a plurality of memory cells each formed as above in a matrix.

The CAM disclosed in the U.S. Pat. No. 6,320,777 has, however, a drawback that it is difficult to reduce a memory cell size when combining the pair of cell units for constituting a memory cell, because of a restriction originating from the circuit configuration.

As already described, each of integrated memory cells of the conventional CAM consists of a combination of the first cell unit U1 and the second cell unit U2 having a symmetrical circuit configuration as shown in FIG. 15, which are disposed vertically adjacent to each other as shown in FIG. 16. Restriction due to the circuit configuration specifically originates from the positioning of the second compare transistor T4 controlled by the first compare line CMP− and the fourth compare transistor T6 controlled by the second compare line CMP+, which are designed to use a source in common for downsizing the circuit scale (the second compare transistor T4 and the fourth compare transistor T6 are commonly connected to the match line ML as shown in FIG. 16), and therefore have to be located close to the boundary I-I between the first cell unit U1 and the second cell unit U2. Also, a space S1 to be provided for insulating purpose between the first bit line BL+ and the second bit line BL−, respectively constituted of a conductive layer in the same lamination, cannot be made smaller than a minimum distance determined by a highest available exposure resolution of a lithography technique to be employed.

Besides, the first bit line BL+ and the second bit line BL− in the conventional CAM are disposed so as to run along the outskirts of the diffusion layer 101A and the diffusion layer 101B and the outskirts of the lower electrode 104A and the lower electrode 104B of the capacitor C1 and the capacitor C2 respectively, therefore the space S1 between the cell unit U1 and the cell unit U2 has to be sufficiently wide. In other words, a space S2 between the diffusion layer 101A and the diffusion layer 101B has been made wider than necessary in the conventional CAM, despite that securing a sufficient width of the space S1 could have automatically secured a sufficient room for the space S2. That is why it has been difficult to reduce a vertical dimension of a memory cell MC.

Further, as shown in FIG. 17, when connecting the lower electrode 104A and the lower electrode 104B (not shown in the drowing) of the pair of capacitor C1 and the capacitor C2 (not shown in the drowing) with the gate line 110A and the gate line 10B (not shown in the drowing) of the first compare transistor T3 and the fourth compare transistor T6, the diffusion layer 101A and the diffusion layer 101B(not shown in the drowing), the contact 107A and the contact 107B(not shown in the drowing), the interconnect 108A and the interconnect 108B (not shown in the drowing), and the contact 109A and the contact 109B (not shown in the drowing) are disposed therebetween. Such configuration inevitably prolongs the connection path between the lower electrode 104A/the lower electrode 104B and the gate line 110A/the gate line 110B respectively, resulting in a drawback of an increased horizontal dimension of a memory cell MC. Besides, disposing the diffusion layer 101A and the diffusion layer 101B on the way of such connection path is prone to incur discharge of the charge accumulated in the capacitor C1 and the capacitor C2 through the diffusion layer 101A and the diffusion layer 101B because of a temperature increase during operation, thereby increasing leakage current that causes errouneous performance.

### SUMMARY OF THE INVENTION

The present invention has been conceived in view of the foregoing situation, with an object to provide a semiconductor storage device that permits reduction of a memory cell size when combining a pair of cell units to constitute a memory cell, because of minimized restriction originating from a circuit configuration.

According to the present invention, there is provided a semiconductor storage device comprising: two pairs of compare transistors respectively connected in series between a ground line and a match line, wherein the two pairs of compare transistors are asymmetrically disposed.

According to the present invention, there is provided a semiconductor storage device comprising: a pair of transistors including a first compare transistor and a second compare transistor connected in series between a ground line and a match line; and a pair of transistors including a third compare transistor and a fourth compare transistor respectively connected in series between the ground line and the match line; a first compare line which controls the second compare transistor; and a second compare line which controls the fourth compare transistor; wherein the first compare transistor and the fourth compare transistor are connected to the ground line, while the second compare transistor and the third compare transistor are connected to the match line.

The semiconductor storage device of the present invention may further comprise: a first capacitor which is connected to the first compare transistor; and a second capacitor which is commected to the third compare transistor.

The semiconductor storage device of the present invention may further comprise: a first memory cell selection transistor a terminal of which is connected to the first compare transitor; a second memory cell selection transistor a terminal of which is connected to the third compare transitor; a word line which controls the first memory cell selection transistor and the second memory cell selection transistor; a first bit line to which the other terminal of the first memory cell selection transistor is connected; and a second bit line to which the other terminal of the second memory cell selection transistor is connected.

In the semiconductor storage device of the present invention, the first capacitor and the second capacitor may respectively include capacitance dielectric films each formed in a plane shape with a recess portion. The recess portion of the capacitance dielectric film of the first capacitor may be disposed right over the first bit line along extending direction of the first bit line. The recess portion of the capacitance dielectric film of the second capacitor may be disposed right over the second bit line along extending direction of the second bit line.

The semiconductor storage device of the present invention may further comprise: a first contact which connects a portion of the first memory cell selection transistor and a lower electrode of the first capacitor; and a second contact which connects a portion of the second memory cell selection transistor and a lower electrode of the second capacitor.

In the semiconductor storage device of the present invention, the first bit line and the second bit line may be respectively disposed so as to pass right below the first capacitor and the second capacitor.

The semiconductor storage device of the present invention may further comprise: a first contact which connects a portion of the first memory cell selection transistor and a lower electrode of the first capacitor; a second contact which connects a portion of the second memory cell selection transistor and a lower electrode of the second capacitor; a third contact which connects the lower electrode of the first capacitor and the first compare transistor; and a fourth contact which connects the lower electrode of the second capacitor and the third compare transistor; wherein the first bit line and the second bit line may be respectively disposed between the first contact and the third contact, and the second contact and the fourth contact so as to pass right below the first capacitor and the second capacitor.

In the semiconductor storage device of the present invention, the first capacitor and the second capacitor may respectively include capacitance dielectric films each formed in a plane shape with a recess portion. The recess portion of the capacitance dielectric film of the first capacitor may be disposed right over the first bit line along extending direction of the first bit line. The recess portion of the capacitance dielectric film of the second capacitor may be disposed right over the second bit line along extending direction of the second bit line. The first bit line and the second bit line may be respetively oriented in a first direction while the first contact and the third contact, and the second contact and the fourth contact may be respectively oriented in a second direction substantially orthogonal to the first direction. The recess portion of the capacitance dielectric film of the first capacitor may be disposed between the first contact and the third contact so as to extend along the first direction. The recess portion of the capacitance dielectric film of the second capacitor may be disposed between the second contact and the fourth contact so as to extend along the first direction.

In the semiconductor storage device of the present invention, the first to fourth compare transistors may be designed to connect the match line and the ground line when a first data stored in the first capacitor and a first comparative data input to the first compare line are detected to be identical, or when a second data stored in the second capacitor and a second comparative data input to the second compare line are detected to be identical.

According to the present inventionm, there is provided a semiconductor storage device comprising: a memory cell provided with a first cell unit and a second cell unit; the first cell unit including a first memory cell selection transistor, a first compare transistor, a second compare transistor, a first capacitor, and a first contact which connects a portion of the first memory cell selection transistor and a lower electrode of the first capacitor; and the second sell unit uncluding a second memory cell selection transistor, a third compare transistor, a fourth compare transistor, a second capacitor, and a second contact which connects a portion of the second memory cell selection transistor and a lower electrode of the second capacitor.

The semiconductor storage device of the present invention may further comprise: a first bit line to which a terminal of the first memory cell selection transistor is connected; and a second bit line to which a terminal of the second memory cell selection transistor is connected, wherein the first bit line and the second bit line may be respectively disposed so as to pass right below the first capacitor and the second capacitor.

In the semiconductor storage device of the present invention, the first capacitor and the second capacitor may respectively include capacitance dielectric films each formed in a plane shape with a recess portion. The recess portion of the capacitance dielectric film of the first capacitor may be disposed right over the first bit line along extending direction of the first bit line. The recess portion of the capacitance dielectric film of the second capacitor may be disposed right over the second bit line along extending direction of the second bit line.

The semiconductor storage device of the present invention may further comprise: a third contact which connects the lower electrode of the first capacitor and the first compare transistor; and a fourth contact which connects the lower electrode of the second capacitor and the third compare transistor; wherein the first bit line and the second bit line may be respectively disposed between the first contact and the third contact, and the second contact and the fourth contact.

In the semiconductor storage device of the present invention, the first capacitor and the second capacitor respectively may include capacitance dielectric films each formed in a plane shape with a recess portion. The recess portion of the capacitance dielectric film of the first capacitor may be disposed right over the first bit line along extending direction of the first bit line. The recess portion of the capacitance dielectric film of the second capacitor may be disposed right over the second bit line along extending direction of the second bit line. The first bit line and the second bit line may be respetively oriented in a first direction, while the first contact and the third contact, and the second contact and the fourth contact may be respectively oriented in a second direction substantially orthogonal to the first direction. The recess portion of the capacitance dielectric film of the first capacitor may be disposed between the first contact and the third contact so as to extend along the first direction and the recess portion of the capacitance dielectric film of the second capacitor may be disposed between the second contact and the fourth contact so as to extend along the first direction.

According to the present invention, there is provided a semiconductor storage device comprising: a memory cell provided with a first cell unit and a second cell unit; the first cell unit including a first memory cell selection transistor, a first compare transistor, a second compare transistor, a first capacitor, and a first bit line connected to the first memory cell selection transistor; and the second sell unit uncluding a second memory cell selection transistor, a third compare transistor, a fourth compare transistor, a second capacitor, and a second contact which connects a portion of the second memory cell selection transistor and a second bit line connected to the second memory cell selection transistor, wherein the first bit line and the second bit line are respectively disposed so as to pass right below the first capacitor and the second capacitor.

In the semiconductor storage device of the present invention, the first capacitor and the second capacitor may respectively include capacitance dielectric films each formed in a plane shape with a recess portion. The recess portion of the capacitance dielectric film of the first capacitor may be disposed right over the first bit line along extending direction of the first bit line, and the recess portion of the capacitance dielectric film of the second capacitor may be disposed right over the second bit line along extending direction of the second bit line.

According to the present invention, there is provided a semiconductor storage device capable of storing and reading out a plurality of data, comprising: a first capacitor which stores a first data; a second capacitor which stores a second data independent from the first data; a first circuit connected to the first capacitor; a first compare line to which a first comparative data is input; a second circuit connected to the first compare line and connected in series with the first circuit; a third circuit connected to the second capacitor; a second compare line to which a second comparative data is input; and a fourth circuit connected to the second compare line and connected in series with the third circuit; and a match line to which the second circuit and the third circuit are connected, wherein the first circuit and the fourth circuit are grounded.

In the semiconductor storage device of the present invention, the first to fourth circuits may be designed to electrically connect the match line and the ground line either when the first data stored in the first capacitor and a first comparative data input to the first compare line are detected to be identical, or when the second data stored in the second capacitor and a second comparative data input to the second compare line are detected to be identical.

In the semiconductor storage device of the present invention, the first comparative data and the second comparative data may be mutually complementary. comparative data are mutually complementary.

The semiconductor storage device of the present invention may be formed as an embedded DRAM.

It is to be noted that any arbitrary combination of the above-described structural components and expressions changed between a method, an apparatus, a system and so forth are all effective as and encompassed by the present embodiments.

Moreover, this summary of the invention does not necessarily describe all necessary features so that the invention may also be sub-combination of these described features.

### BRIEF DESCRIPTION OF THE DRAWINGS

FIG. 1 is a circuit diagram of a semiconductor storage device according to a first embodiment of the present invention.

FIG. 2 is a schematic plan view showing a semiconductor storage device integrated according to the circuit configuration of FIG. 1.

FIG. 3 is a schematic cross-setional view taken along the line A-A of FIG. 2.

FIG. 4 is a schematic cross-setional view taken along the line B-B of FIG. 2.

FIG. 5 is a schematic cross-setional view taken along the line C-C of FIG. 2.

FIG. 6 is a schematic cross-setional view taken along the line D-D of FIG. 2.

FIG. 7 is a schematic plan view showing a semiconductor storage device according to a second embodiment of the present invention.

FIG. 8 is a schematic plan view showing a semiconductor storage device according to a third embodiment of the present invention.

FIG. 9 is a schematic cross-setional view taken along the line A-A of FIG. 8.

FIG. 10 is a schematic cross-setional view taken along the line B-B of FIG. 8.

FIG. 11 is a schematic cross-setional view taken along the line C-C of FIG. 8.

FIG. 12 is a schematic plan view of a main portion of a capacitor used in a semiconductor storage device according to a fourth embodiment of the present invention.

FIG. 13 is a schematic cross-sectional view taken along the line J-J of FIG. 12.

FIG. 14 is a schematic cross-sectional view taken along the line K-K of FIG. 12.

FIG. 15 is a circuit diagram of a conventional semiconductor storage device.

FIG. 16 is a schematic plan view showing a semiconductor storage device integrated according to the circuit configuration of FIG. 15.

FIG. 17 is a schematic cross-sectional view taken along the line E-E of FIG. 16.

FIG. 18 is a schematic cross-sectional view taken along the line F-F of FIG. 16.

FIG. 19 is a schematic cross-sectional view taken along the line G-G of FIG. 16.

### DETAILED DESCRIPTION OF THE INVENTION

The invention will now be described based on preferred embodiments which do not intend to limit the scope of the present invention but exemplify the invention. All of the features and the combinations thereof described in the embodiment are not necessarily essential to the invention.

First Embodiment

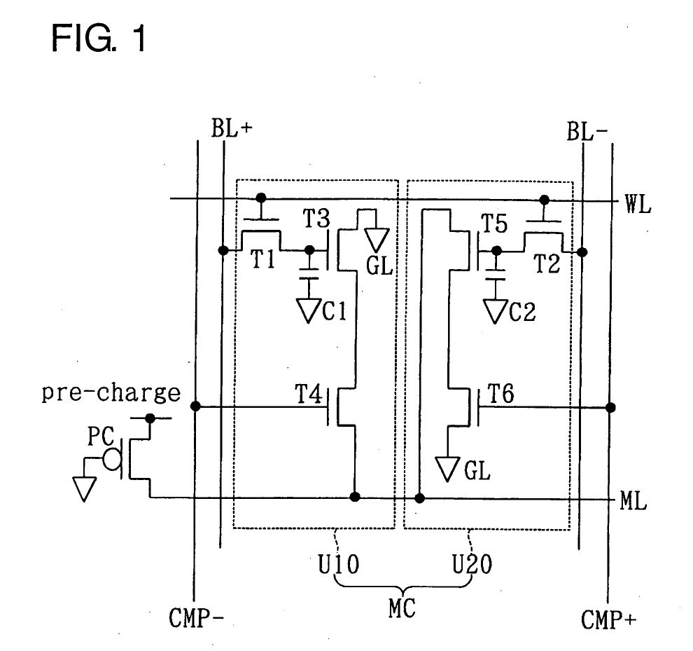

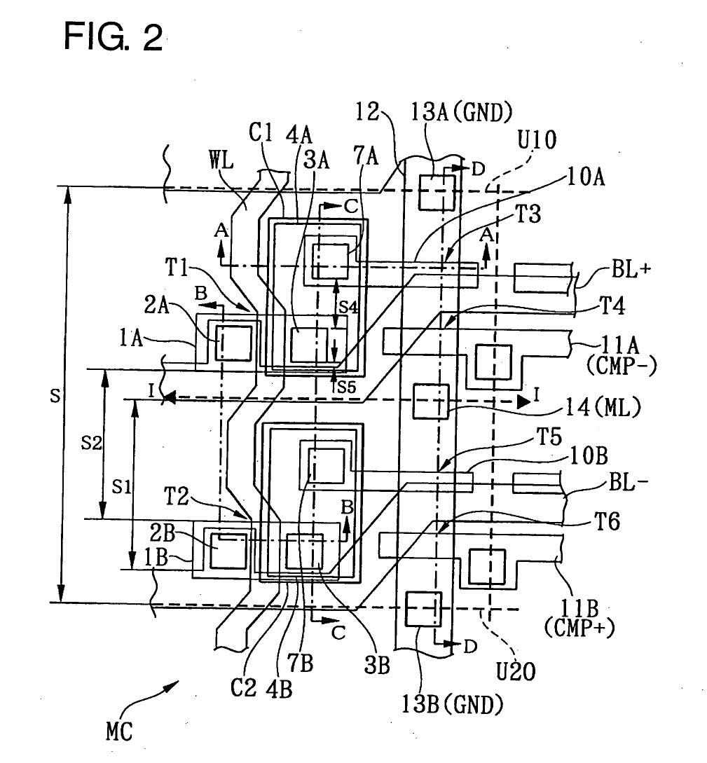

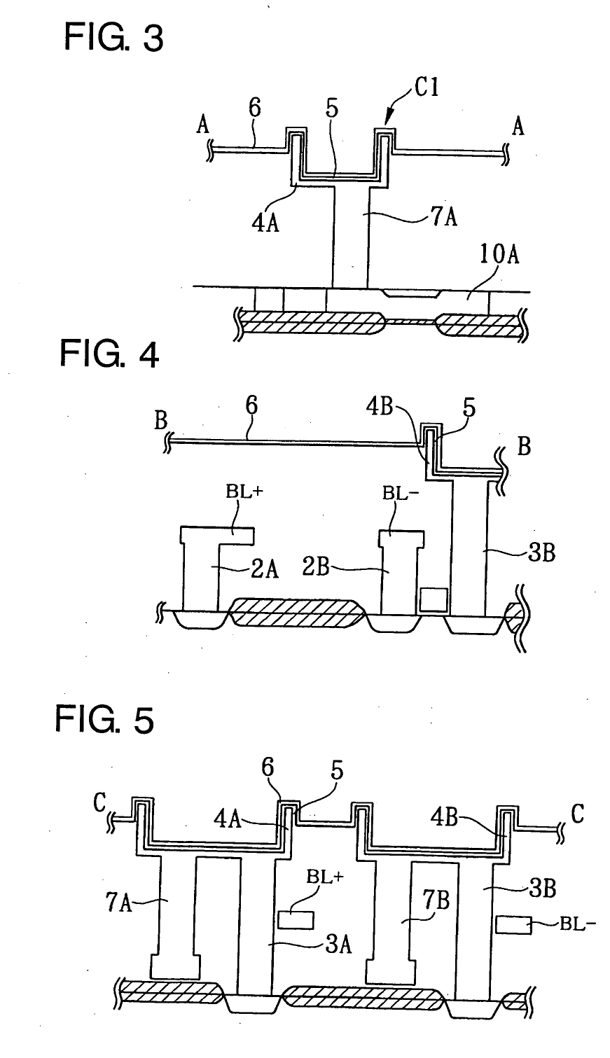

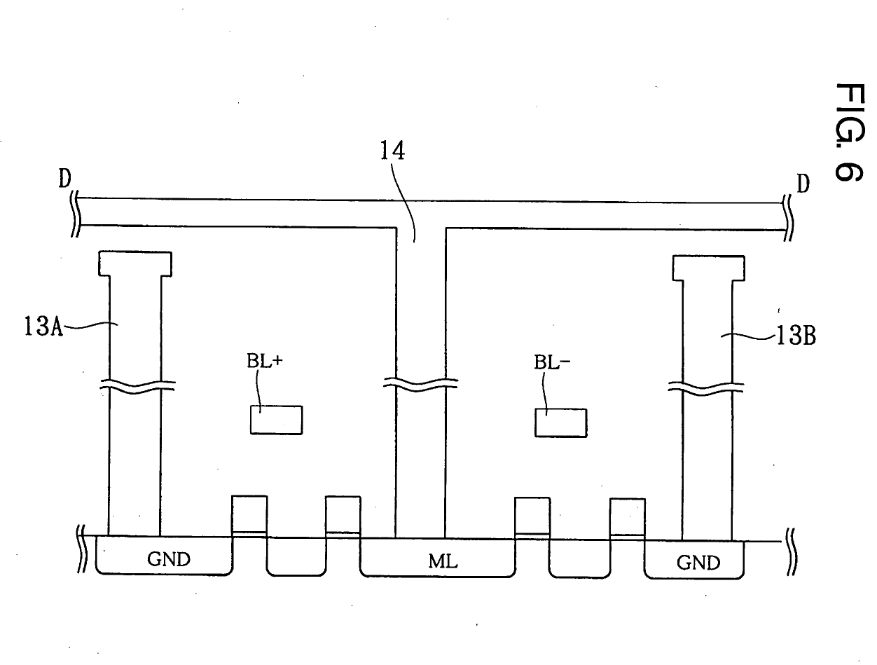

FIG. 1 is a circuit diagram of a semiconductor storage device according to a first embodiment of the present invention. FIG. 2 is a plan view showing a semiconductor storage device manufactured (integrated) according to the circuit configuration of FIG. 1. FIG. 3 is a cross-setional view taken along the line A-A of FIG. 2. FIG. 4 is a cross-setional view taken along the line B-B of FIG. 2. FIG. 5 is a cross-setional view taken along the line C-C of FIG. 2. FIG. 6 is a cross-setional view taken along the line D-D of FIG. 2.

As shown in FIG. 1, the semiconductor storage device (CAM) according to this embodiment is provided with a first cell unit U10 including a first memory cell selection transistor T1, a first compare transistor T3, a second compare transistor T4 and a first capacitor C1, and a second cell unit U20 including a second memory cell selection transistor T2, a third compare transistor T5, a fourth compare transistor T6 and a second capacitor C2. The cell units U10 and U20 are asymmetrically configurated.

The first memory cell selection transistor T1 and the second memory cell selection transistor T2 are controlled by a word line WL. A pair of transistors including the first compare transistor T3 and the second compare transistor T4, and a pair of transistors including the third compare transistor T5 and the fourth compare transistor T6 are respectively connected in series between a ground line GL and a match line ML. The first capacitor C1 and the second capacitor C2 are respectively connected to a terminal of the first memory cell selection transistor T1 and the second memory cell selection transistor T2 and to a gate of the first compare transistor T3 and the third compare transistor T5. The other terminal of the first memory cell selection transistor T1 and that of the memory cell selection transistor T2 are respectively connected to a first bit line BL+ and a second bit line BL−. The second compare transistor T4 and the fourth compare transistor T6 are respectively controlled by a first compare line CMP− and a second compare line CMP+.

In this embodiment, the first compare transistor T3 connected to the first capacitor C1 is connected to the ground line GL in the cell unit U10. By contrast, in the cell unit U20, the third compare transistor T5 connected to the capacitor C2 is connected to the match line ML.

Also, in the cell unit U10, the second compare transistor T4 controlled by the first compare line CMP− is connected to the match line ML. By contrast, in the cell unit U20, the fourth compare transistor T6 controlled by the second compare line CMP+ is connected to the ground line GL.

The CAM constituted of such DRAM is provided with a storage function as well as a logic function as represented by the Table 1 described earlier in the description of the related art. Therefore, the circuit configuration according to FIG. 1 constitutes a ternary CAM.

As already stated, the first cell unit U10 and the second cell unit U20 are asymmetrically configurated in this embodiment, wherein a specific difference from the conventional symmetrical configuration of the first cell unit U1 and the second cell unit U2 is that the fourth compare transistor T6, to which the capacitor C2 is not connected, is connected to the ground line GL, in the second cell unit U20. In other words, the first compare transistor T3 with its gate connected to the capacitor C1 and the fourth compare transistor T6 with its gate connected to the second compare line CMP+ are connected to the ground line GL, while the third compare transistor T5 with its gate connected to the second capacitor C2 and the second compare transistor T4 with its gate connected to the first compare line CMP− are connected to the match line ML. Such asymmetrical configuration of the first cell unit U10 and the second cell unit U20 facilitates minimizing restriction originating from circuit configuration when designing a memory cell with a pair of cell unit, as will be described in details in the following.

As shown in FIG. 2, the semiconductor storage device integrated in accordance with the circuit configuration of FIG. 1 includes the first cell unit U10 and the second cell unit U20 disposed side by side in a vertical direction of the drawing, oriented in a same direction. In other words the first cell unit U10 and the second cell unit U20 are asymmetrically disposed with respect to a plane orthogonally intersecting with the drawing through the boundary I-I.

The first bit line BL+ of the first cell unit U10 is laterally disposed along the outskirts of a lower electrode 4A of the first capacitor C1 formed in an upper layer of the first bit line BL+. The first bit line BL+ is connected to a diffusion layer 1A constituting a source (or drain) region of the first memory cell selection transistor T1 via a contact 2A. The diffusion layer 1A constituting a drain (or source) region of the first memory cell selection transistor T1 is connected to the lower electrode 4A of the first capacitor C1, for example cylindrically shaped, via a contact 3A. The lower electrode 4A is connected to a gate line 10A of the first compare transistor T3 via a contact 7A disposed right below the lower electrode 4A. An upper electrode 6 confronting the lower electrode 4A of the first capacitor C1 via a capacitance dielectric film 5 serves as an electrode to be used in common for all the memory cells.

Also, a diffusion layer 12 constituting a source (or drain) region of the first compare transistor T3 and the second compare transistor T4 is provided in a vertical direction of the drawing, and a gate line 10A and a gate line 11A of the first compare transistor T3 and the second compare transistor T4 respectively are disposed on an upper layer of the diffusion layer 12. Here, the gate line 11A is connected to the first compare line CMP−.

Likewise, the second bit line BL− of the second cell unit U20 is laterally disposed along the outskirts of a lower electrode 4B of the second capacitor C2 formed in an upper layer of the second bit line BL−. The second bit line BL− is connected to a diffusion layer 1B constituting a source (or drain) region of the second memory cell selection transistor T2 via a contact 2B. The diffusion layer 1B constituting a drain (or source) region of the second memory cell selection transistor T2 is connected to the lower electrode 4B of the second capacitor C2, for example cylindrically shaped, via a contact 3B. The lower electrode 4B is connected to a gate line 10B of the third compare transistor T5 via a contact 7B disposed right below the lower electrode 4B. The upper electrode 6 confronting the lower electrode 4B of the second capacitor C2 via the capacitance dielectric film 5 serves as an electrode to be used in common for all the memory cells.

Also, a gate line 10B and a gate line 11B of the third compare transistor T5 and the fourth compare transistor T6 respectively are disposed in an upper layer of the diffusion layer 12. The gate line 11B is connected to the second compare line CMP+. Further, a word line WL is provided in a vertical direction of the drawing, and a contact 13A and a contact 13B connected to the ground line GL, as well as a contact 14 connected to the match line ML are disposed on the diffusion layer 12.

The CAM of this embodiment is constituted of a plurality of memory cells each formed as above disposed in a matrix array.

As stated with referring to FIG. 1, the second compare transistor T4 controlled by the first compare line CMP− is connected to the match line ML, and the fourth compare transistor T6 controlled by the second compare line CMP+ is connected to the ground line GL in the CAM of this embodiment. Accordingly, the second compare transistor T4 and the fourth compare transistor T6 do not share a drain, which eliminates the need of disposing the second compare transistor T4 and the fourth compare transistor T6 close to the boundary I-I between the first cell unit U10 and the second cell unit U20 as shown in FIG. 2.

By contrast, since the second compare transistor T4 and the third compare transistor T5 connected to the second capacitor C2 are both connected to the match line ML, they share a drain. Therefore, the second compare transistor T4 and the third compare transistor T5 have to be located close to the boundary I-I between the first cell unit U10 and the second cell unit U20 as shown in FIG. 2. Consequently, the first compare transistor T3 connected to the first capacitor C1 is located at a certain distance from the boundary I-I between the first cell unit U10 and the second cell unit U20.

Because of such configuration, the contact 3A is located close to the boundary I-I between the first cell unit U10 and the second cell unit U20. Therefore, the first bit line BL+ is disposed close to the boundary I-I. By contrast, since the contact 3B is located away from the boundary I-I, the second bit line BL− is disposed away from the boundary I-I.

Accordingly, the first cell unit U10 and the second cell unit U20 in the CAM of this embodiment are asymmetrically disposed in a device with respect to a plane orthogonally intersecting with the drawing through the boundary I-I as shown in FIG. 2, which eliminates the need of disposing the first bit line BL+ and the second bit line BL− side by side. Therefore, a space S1 between the first bit line BL+ and the second bit line BL− can be reduced to the same extent of reducing a space S2 between the diffusion layer 1A and the diffusion layer 1B to a minimum possible distance. In other words, a separation between the first cell unit U10 and the second cell unit U20 can be reduced as much as reducing the space S2 to a minimum possible distance, without taking the space S1 into consideration. Consequently, the configuration facilitates reducing a size S of the memory cell MC in a vertical direction.

As described above, according to the semiconductor storage device of this embodiment, a memory cell MC including a pair of the first memory cell selection transistor T1 and the second memory cell selection transistor T2 controlled by the word line WL; a pair of transistors including the first compare transistor T3 and the second compare transistor T4 respectively connected in series between the ground line GL and the match line ML; a pair of transistors including the third compare transistor T5 and the fourth compare transistor T6; and a pair of capacitors C1 and C2 respectively connected between the upper electrode and a contact between a terminal of the first memory cell selection transistor T1 and the seconde memory cell selection transistor T2 and a gate of the first compare transistor T3 and the third compare transistor T5 is provided. The other terminal of the first memory cell selection transistor T1 and that of the second memory cell selection transistor T2 are respectively connected to the first bit line BL+ and the second bit line BL−, and the second compare transistor T4 and the fourth compare transistor T6 are respectively controlled by the first compare line CMP− and the second compare line CMP+. And then the first cell unit U10 including the first memory cell selection transistor T1, the first compare transistor T3, the second compare transistor T4 and the first capacitor C1, and the second cell unit U20 including the second memory cell selection transistor T2, the third compare transistor T5, the fourth compare transistor T6 and the seconed capacitor C2 are asymmetrically disposed with respect to a plane orthogonally intersecting with the drawing through the boundary I-I. As a result, a vertical dimension of a memory cell can be reduced.

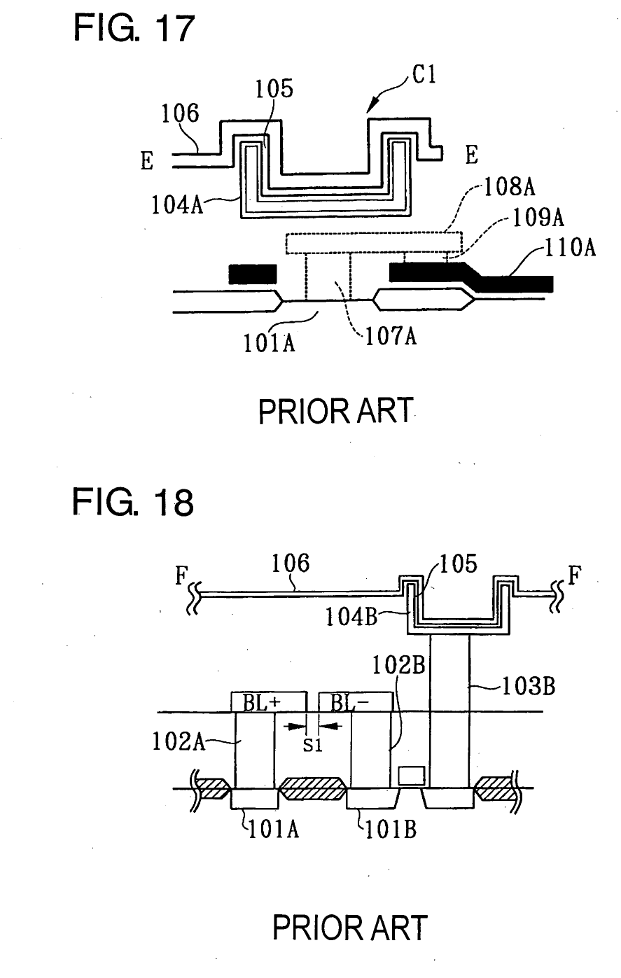

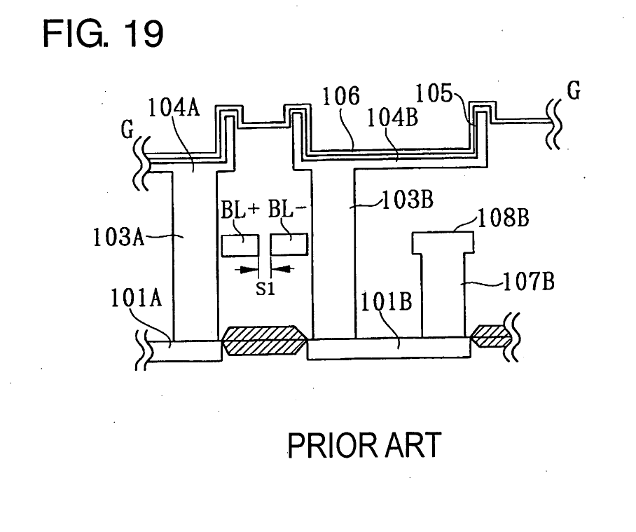

Also in this embodiment, as shown in FIG. 3, the connection of the lower electrode 4A and the lower electrode 4B (not shown in the drawing) of the first capacitor C1 and the second capacitor C2 (not shown in the drawing) with the gate line 10A and the gate line 10B (not shown in the drawing) of the first compare transistor T3 and the third compare transistor T5 is achieved via the contact 7A and the contact 7B (not shown in the drawing) disposed right below the lower electrode 4A and the lower electrode 4B (not shown in the drawing). Such configuration eliminates the need of a long connection path including the diffusion layer 101A and the diffusion layer 101B, the contact 107A and the contact 107B, the interconnect 108A and the interconnect 108B, and the contact 109A and the contact 109B as seen in the conventional device such as shown in FIG. 17. Therefore the connection path can be shortened, which provides an additional advantage of reducing a horizontal dimension of the memory cell MC.

Further referring to FIG. 3, in this embodiment, a diffusion layer is not included in the connection path between the lower electrode 4A and the lower electrode 4B (not shown in the drawing) of the first capacitor C1 and the second capacitor C2 (not shown in the drawing) and the gate line 10A and the gate line 10B (not shown in the drawing) of the first compare transistor T3 and the third compare transistor T5 unlike the conventional device, which prevents discharge of the charge accumulated in the first capacitor C1 and the second capacitor C2 through the diffusion layer during operation, and leakage current can therefore be reduced.

Second Embodiment

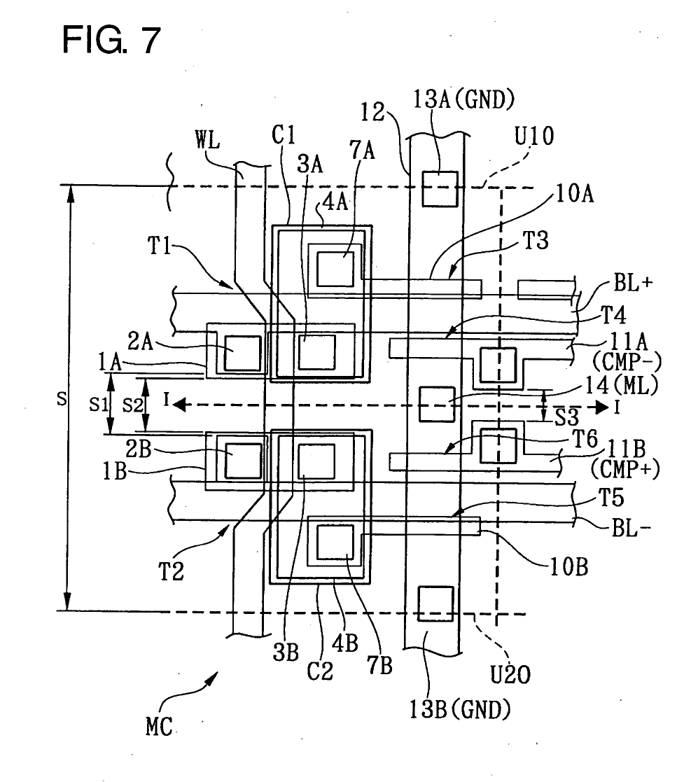

FIG. 7 is a schematic plan view showing a semiconductor storage device according to a second embodiment of the present invention. A significant difference of the semiconductor storage device according to the second embodiment from that of the first embodiment is that the first cell unit and the second cell unit are symmetrically disposed.

As shown in FIG. 7, the semiconductor storage device (CAM) of this embodiment is provided with the first cell unit U10 and the second cell unit U20 symmetrically disposed with respect to a plane orthogonally intersecting with the drawing through the boundary I-I. The first bit line BL+ and the second bit line BL− are disposed between the contacts 3A and 3B and the contacts 7A and 7B, and extends along a region right below the first capacitor C1 and the second capacitor C2, respectively. Here, the contacts 3A and 3B connect a portion of the first memory cell selection transistor T1 region and the second memory cell selection transistor T2 with the lower electrode 4A and the lower electrode 4B of the first capacitor C1 and the second capacitor C2, respectively. The contacts 7A and 7B connect the lower electrode 4A and the lower electrode 4B of the first capacitor C1 and the second capacitor C2 with the first compare transistor T3 and third compare transistor T5, respectively. In other words, the first compare transistor T3 and third compare transistor T5 with their respective gates connected to the capacitors C1 and C2 are connected to the ground line GL, while the second compare transistor T4 and the fourth compare transistor T6 with their respective gates connected to the first compare line CMP− and the second compare line CMP+ are connected to the match line ML.

The remaining portion of the configuration of this embodiment is substantially the same as that of the first embodiment. Therefore, components in FIG. 7 corresponding to those in FIG. 2 are given the identical numerals, and description thereof will be omitted.

As a result of such configuration, the first bit line BL+ and the second bit line BL− are respectively disposed in a region right below the lower electrode 4A and the lower electrode 4B of the first capacitor C1 and the second capacitor C2. Accordingly, as in the first embodiment, the first cell unit U10 and the second cell unit U20 can be located closer to each other to the same extent of reducing the space S2 between the the diffusion layer 1A and the diffusion layer 1B to a minimum possible distance. Consequently a vertical dimension of the memory cell MC can be reduced. Also, since the lower electrode 4A and the lower electrode 4B of the first capacitor C1 and the second capacitor C2 are respectively connected to the gate line 10A and the gate line 10B of the first compare transistor T3 and the third compare transistor T5 via the contact 7A and the contact 7B, the connection path can be shortened, which provides an additional advantage of reducing a horizontal dimension of the memory cell MC. Further, since a diffusion layer is not included in the connection path, discharge of the charge accumulated in the first capacitor C1 and the second capacitor C2 through the diffusion layer during operation can be prevented, and leakage current can therefore be reduced.

Accordingly, the configuration of the second embodiment where the first cell unit and the second cell unit are symmetrically disposed can also provide substantially the same benefit to that of the first embodiment.

Third Embodiment

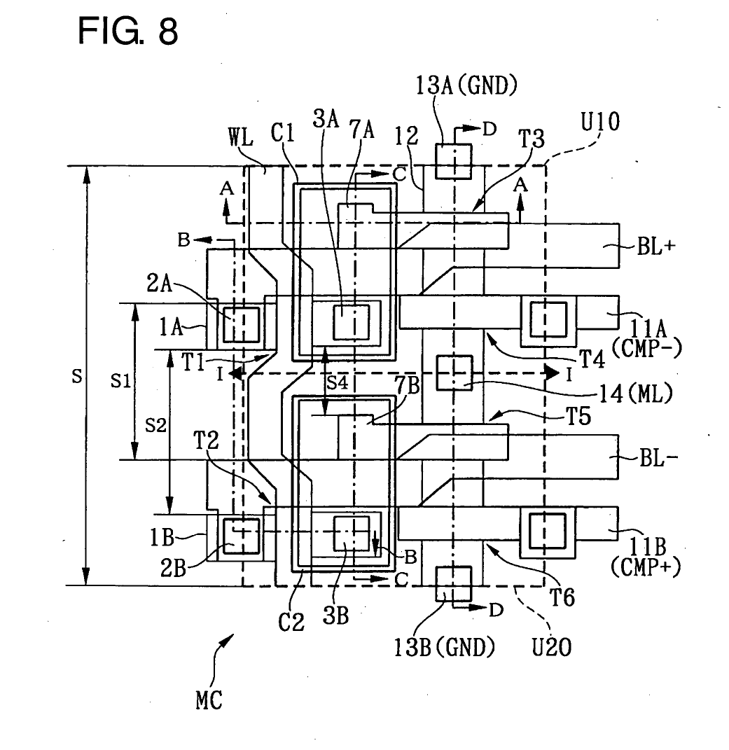

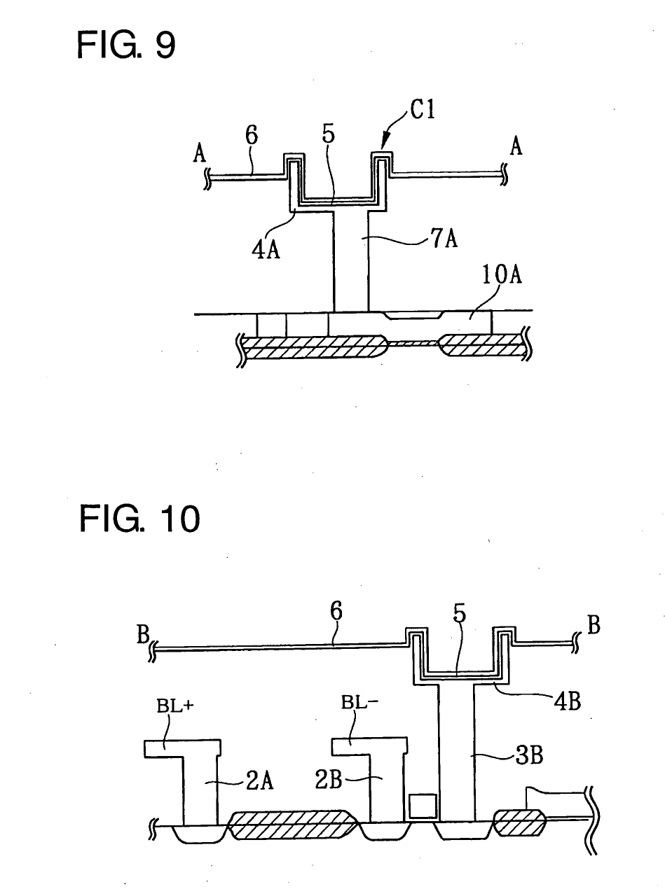

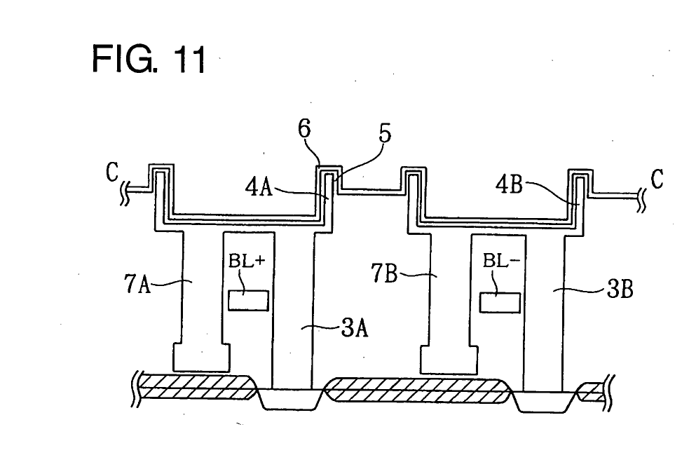

FIG. 8 is a plan view showing a semiconductor storage device according to a third embodiment of the present invention. FIG. 9 is a cross-setional view taken along the line A-A of FIG. 8. FIG. 10 is a cross-setional view taken along the line B-B of FIG. 8. FIG. 11 is a cross-setional view taken along the line C-C of FIG. 8. Here, a cross-sectional view taken along the line D-D is identical with FIG. 6 and therefore the cross-sectional view taken along the line D-D is not shown. A significant difference of the semiconductor storage device according to the third embodiment from that of the first embodiment is that the first bit line BL+ and the second bit line BL− are respectively disposed between a pair of contacts below the first capacitor C1 and the second capacitor C2 as in the second embodiment, with the first cell unit and the second cell unit asymmetrically disposed.

As shown in FIG. 8, the semiconductor storage device (CAM) of this embodiment is provided with the first cell unit U10 and the second cell unit U20 asymmetrically disposed with respect to a plane orthogonally intersecting with the drawing through the boundary I-I. The first bit line BL+ and the second bit line BL− are respectively disposed between the contacts 3A and 3B and the contacts 7A and 7B, and extends along a region right below the first capacitor C1 and the second capacitor C2.

In this embodiment, disposing the first bit line BL+ and the second bit line BL− between the contact 3A, the contact 3B and the contact 7A, the contact 7B as above offers a benefit that a cylinder size of the first capacitor C1 and the second capacitor C2 can be made greater, though a cell unit size itself remains unchanged. Specifically, in the first embodiment shown in FIG. 2, a space between the contacts, i.e. between the contact 3A and the contacts 7A, and the contact 3B and the contact 7B, respectively, can be reduced to S4. However actually a space S5 for the contact 3A and the bit line BL+, and the contact 3B and the bit line BL-, respectively, has to be taken into account in order to dispose the first to fourth compare transistors T3 to T6 along the right-hand side of the first capacitor C1 and the second capacitor C2. Therefore the cell unit size becomes greater in a vertical direction. Accordingly, in order to make up for the increase, the space is allocated for disposing the first bit line BL+ and the second bit line BL− outside the cylinder of the first capacitor C1 and the second capacitor C2 in the first embodiment. On the other hand, in this embodiment, the space is allocated for disposing the first bit line BL+ and the second bit line BL− inside the cylinder of the first capacitor C1 and the second capacitor C2. Consequently, since a cylinder size of the first capacitor C1 and the second capacitor C2 can be made greater in this embodiment, though the cell unit size itself remains unchanged, a greater circuit operation margin can be secured.

Also, by asymmetrically disposing the first cell unit U10 and the second cell unit U20 according to this embodiment, the pair of transistors including the first compare transistor T3 and the second compare transistor T4 and the pair of transistors including the third compare transistor T5 and the fourth compare transistor T6 are also asymmetrically disposed. Therefore the cell size can be reduced to a greater extent than in the second embodiment. The reason is given below.

In the second embodiment, a distance between the cell units is determined by:

S2=minimum distance between the diffusion layers+alignment margin of the contact;

S3=minimum distance between the gates+alignment margin of the contact;

while in the third embodiment a distance between the cell units is determined by:

S4=distance between the contacts.

In general, exposure equipments of a same generation are employed in the forming process of a diffusion layer, a gate or a contact; therefore a limit of resolution is also substantially the same in each process. Accordingly, the minimum distance between the diffusion layers, the minimum distance between the gates and the distance between the contacts (S4) are similar values to one another. Consequently, the formulas of S2 and S3 can be converted as:

S2=S4+alignment margin for the contact (diffusion layer misstep margin)

S3=S4+alignment margin for the contact (gate misstep margin) Since it is obvious that S4 is smaller than S2 and S3 in view of the converted formula, the cell size can be made smaller than in the second embodiment.

As described above, according to the third embodiment, the cell size can be made smaller than in the second embodiment, and also the cylinder size can be made greater in the cell unit of the same size as that of the first embodiment.

Fourth Embodiment

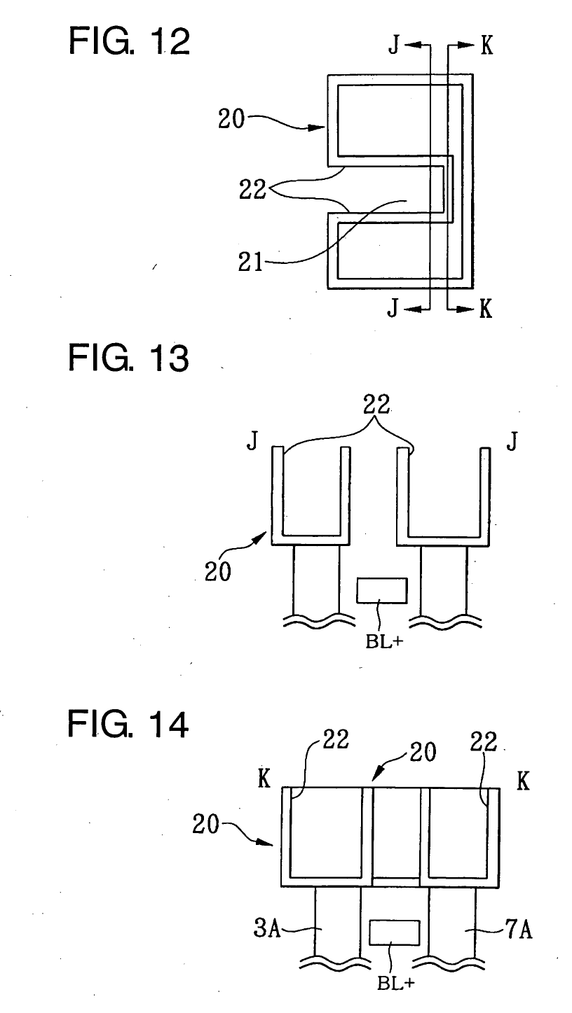

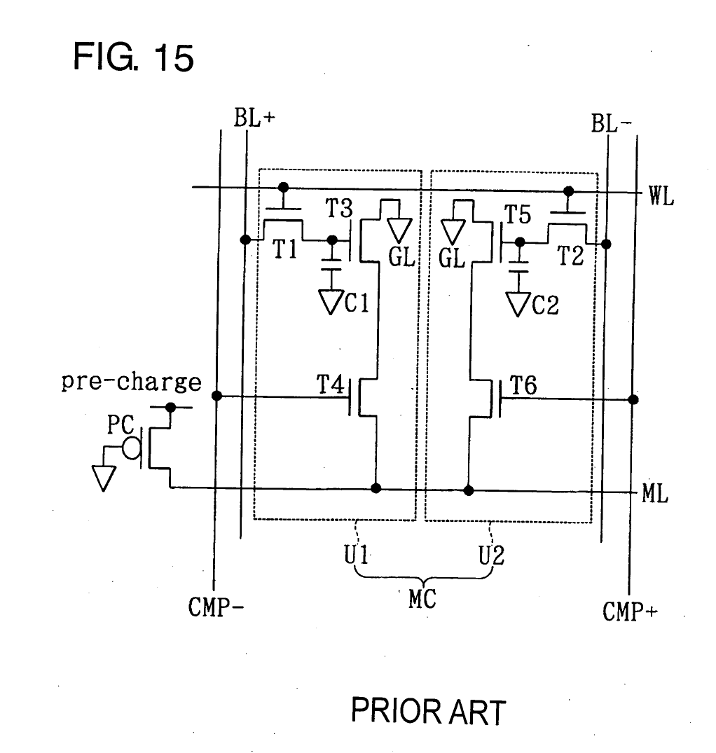

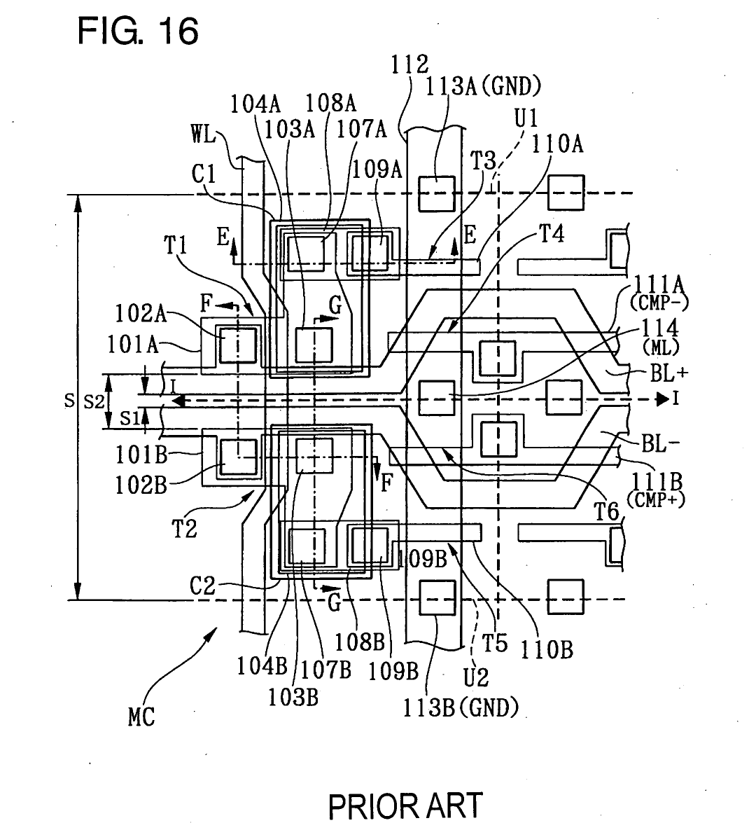

FIG. 12 is a plan view of a main portion of a capacitor used in a semiconductor storage device according to a fourth embodiment of the present invention. FIG. 13 is a cross-sectional view taken along the line J-J of FIG. 13. FIG. 14 is a cross-sectional view taken along the line K-K of FIG. 13. A significant difference of the semiconductor storage device according to the fourth embodiment from that of the second and the third embodiments is that the cylindrical shape of the capacitor is changed for still better performance.

The capacitor to be employed in the semiconductor storage device of this embodiment, which is applied to the first capacitor C1 and the second capacitor C2 in the second and the third embodiment, is provided with a capacitance dielectric film 20 of a cylindrical shape having a recessed rectangular cross-section with a recess portion 21 as shown in FIGS. 12 to 14. The capacitance dielectric film 20 of such shape has an increased contact area with an electrode than a simple rectangular shaped capacitance dielectric film, by an amount corresponding to the lateral walls 22 along the recess portion 21; therefore a capacity of the capacitor constituting the DRAM can be made greater, utilizing the capacitance dielectric film of the identical material. Especially in case of adopting a multilayer structure, the effect of the increase becomes more significant. Alternatively, in case where it is not necessary to increase the capacity, the layout area can be made smaller by the amount corresponding to the lateral walls 22 along the recess portion 21.

Further, in a configuration where the first bit line BL+ and the second bit line BL− are disposed between the contact 3A and the contact 7A or between the contact 3B and the contact 7B of the first capacitor C1 and the second capacitor C2, respectively, disposing the capacitance dielectric film 20 such that an overlapping area with the first bit line BL+ and the second bit line BL− becomes the minimum leads to a decrease of the overlapping area of the capacitance dielectric film 20 with the first bit line BL+ and the second bit line BL−. Therefore emergence of a floating capacitance between the capacitance dielectric film 20 and the first bit line BL+ or the second bit line BL−, which may cause erroneous performance of the device, can be reduced. In this embodiment, the lower electrode 4A and the lower electrode 4B of the first capacitor C1 and the second capacitor C2 are respectively formed in a shape with a recess corresponding to the recess portion 21, for each of the first cell unit U10 and the second cell unit U20 independently.

The remaining portion of the configuration of this embodiment is substantially the same as that of the second and the third embodiment. Thus the description will be omitted.

Accordingly, the configuration of this embodiment permits reducing the cell size to a substantially same extent as in the second and the third embodiments, and increasing a contact area of the capacitance dielectric film of the first capacitor and the second capacitor with an electrode.

In addition, the configuration of this embodiment permits securing a certain capacity level of the capacitor with a relatively small layout area, and decreasing an overlapping area of the capacitance dielectric film and the bit line, thereby effectively minimizing a floating capacitance which is prone to cause erroneous performance of the device.

Although the present invention has been described byway of exemplary embodiments, it should be understood that many changes and substitutions may further be made by those skilled in the art without departing from the scope of the present invention which is defined by the appended claims.

To cite a few examples, structure of a capacitor of a DRAM is not specifically limited, but may be an MIM (Metal Insulator Metal) structure in which a lower electrode and an upper electrode are made of a metal material, or another structure in which a polycrystalline silicone is used for any such electrode.

Also, while MOS transistors are employed for constituting a CAM in the foregoing embodiments, it is also possible to employ a nitride film to constitute a gate dielectric film, an MIS (Metal Insulator Semiconductor) transistor, an MNS (Metal Nitride Semiconductor) transistor, or an MNOS (Metal Nitride Oxide Semiconductor) transistor provided with a dual film made of an oxide film and a nitride film.

What is claimed is:

1. A semiconductor storage device comprising:
two pairs of compare transistors respectively connected in series between a ground line and a match line,
wherein said two pairs of compare transistors are asymmetrically disposed.

2. A semiconductor storage device comprising:
a pair of transistors including a first compare transistor and a second compare transistor connected in series between a ground line and a match line; and
a pair of transistors including a third compare transistor and a fourth compare transistor respectively connected in series between said ground line and said match line;
a first compare line which controls said second compare transistor; and
a second compare line which controls said fourth compare transistor;
wherein said first compare transistor and said fourth compare transistor are connected to said ground line, while said second compare transistor and said third compare transistor are connected to said match line.

3. The semiconductor storage device as set forth in claim 2, further comprising:
a first capacitor which is connected to said first compare transistor; and
a second capacitor which is commected to said third compare transistor.

4. The semiconductor storage device as set forth in claim 3, further comprising:
a first memory cell selection transistor a terminal of which is connected to said first compare transitor;
a second memory cell selection transistor a terminal of which is connected to said third compare transitor;
a word line which controls said first memory cell selection transistor and said second memory cell selection transistor;
a first bit line to which the other terminal of said first memory cell selection transistor is connected; and
a second bit line to which the other terminal of said second memory cell selection transistor is connected.

5. The semiconductor storage device as set forth in claim 4, wherein said first capacitor and said second capacitor respectively include capacitance dielectric films each formed in a plane shape with a recess portion, said recess portion of said capacitance dielectric film of said first capacitor being disposed right over said first bit line along extending direction of said first bit line, and said recess portion of said capacitance dielectric film of said second capacitor being disposed right over said second bit line along extending direction of said second bit line.

6. The semiconductor storage device as set forth in claim 4 further comprising:
a first contact which connects a portion of said first memory cell selection transistor and a lower electrode of said first capacitor; and
a second contact which connects a portion of said second memory cell selection transistor and a lower electrode of said second capacitor.

7. The semiconductor storage device as set forth in claim 4, wherein said first bit line and said second bit line are respectively disposed so as to pass right below said first capacitor and said second capacitor.

8. The semiconductor storage device as set forth in claim 4 further comprising:
a first contact which connects a portion of said first memory cell selection transistor and a lower electrode of said first capacitor;
a second contact which connects a portion of said second memory cell selection transistor and a lower electrode of said second capacitor;
a third contact which connects said lower electrode of said first capacitor and said first compare transistor; and
a fourth contact which connects said lower electrode of said second capacitor and said third compare transistor;
wherein said first bit line and said second bit line are respectively disposed between said first contact and said third contact, and said second contact and said fourth contact so as to pass right below said first capacitor and said second capacitor.

9. The semiconductor storage device as set forth in claim 8, wherein said first capacitor and said second capacitor respectively include capacitance dielectric films each formed in a plane shape with a recess portion, said recess portion of said capacitance dielectric film of said first capacitor being disposed right over said first bit line along extending direction of said first bit line, said recess portion of said capacitance dielectric film of said second capacitor being disposed right over said second bit line along extending direction of said second bit line, said first bit line and said second bit line being respetively oriented in a first direction, said first contact and said third contact, and said second contact and said fourth contact being respectively oriented in a second direction substantially orthogonal to said first direction, said recess portion of said capacitance dielectric film of said first capacitor being disposed between said first contact and said third contact so as to extend along said first direction; and said recess portion of said capacitance dielectric film of said second capacitor being disposed between said second contact and said fourth contact so as to extend along said first direction.

10. The semiconductor storage device as set forth in claim 3, wherein said first to fourth compare transistors are designed to electrically connect said match line and said ground line when a first data stored in said first capacitor and a first comparative data input to said first compare line are detected to be identical, or when a second data stored in said second capacitor and a second comparative data input to said second compare line are detected to be identical.

11. A semiconductor storage device comprising:
a memory cell provided with a first cell unit and a second cell unit;
said first cell unit including a first memory cell selection transistor, a first compare transistor, a second compare transistor, a first capacitor, and a first contact which connects a portion of said first memory cell selection transistor and a lower electrode of said first capacitor; and
said second sell unit uncluding a second memory cell selection transistor, a third compare transistor, a fourth compare transistor, a second capacitor, and a second contact which connects a portion of said second memory cell selection transistor and a lower electrode of said second capacitor.

12. The semiconductor storage device as set forth in claim 11 further comprising:
a first bit line to which a terminal of said first memory cell selection transistor is connected; and
a second bit line to which a terminal of said second memory cell selection transistor is connected,
wherein said first bit line and said second bit line are respectively disposed so as to pass right below said first capacitor and said second capacitor.

13. The semiconductor storage device as set forth in claim 1, wherein said first capacitor and said second capacitor respectively include capacitance dielectric films each formed in a plane shape with a recess portion, wherein said recess portion of said capacitance dielectric film of said first capacitor is disposed right over said first bit line along extending direction of said first bit line, and said recess portion of said capacitance dielectric film of said second capacitor is disposed right over said second bit line along extending direction of said second bit line.

14. The semiconductor storage device as set forth in claim 11 further comprising:
a third contact which connects said lower electrode of said first capacitor and said first compare transistor; and
a fourth contact which connects said lower electrode of said second capacitor and said third compare transistor;
wherein said first bit line and said second bit line are respectively disposed between said first contact and said third contact, and said second contact and said fourth contact.

15. The semiconductor storage device as set forth in claim 14, wherein said first capacitor and said second capacitor respectively include capacitance dielectric films each formed in a plane shape with a recess portion, said recess portion of said capacitance dielectric film of said first capacitor being disposed right over said first bit line along extending direction of said first bit line, said recess portion of said capacitance dielectric film of said second capacitor being disposed right over said second bit line along extending direction of said second bit line, said first bit line and said second bit line being respetively oriented in a first direction, said first contact and said third contact, and said second contact and said fourth contact being respectively oriented in a second direction substantially orthogonal to said first direction, said recess portion of said capacitance dielectric film of said first capacitor being disposed between said first contact and said third contact so as to extend along said first direction; and said recess portion of said capacitance dielectric film of said second capacitor being disposed between said second contact and said fourth contact so as to extend along said first direction.

16. A semiconductor storage device comprising:
a memory cell provided with a first cell unit and a second cell unit;
said first cell unit including a first memory cell selection transistor, a first compare transistor, a second compare transistor, a first capacitor, and a first bit line connected to said first memory cell selection transistor; and
said second sell unit uncluding a second memory cell selection transistor, a third compare transistor, a fourth compare transistor, a second capacitor, and a second contact which connects a portion of said second memory cell selection transistor and a second bit line connected to said second memory cell selection transistor,
wherein said first bit line and said second bit line are respectively disposed so as to pass right below said first capacitor and said second capacitor.

17. The semiconductor storage device as set forth in claim 16, wherein said first capacitor and said second capacitor respectively include capacitance dielectric films each formed in a plane shape with a recess portion, wherein said recess portion of said capacitance dielectric film of said first capacitor is disposed right over said first bit line along extending direction of said first bit line, and said recess portion of said capacitance dielectric film of said second capacitor is disposed right over said second bit line along extending direction of said second bit line.

18. A semiconductor storage device capable of storing and reading out a plurality of data, comprising:
a first capacitor which stores a first data;
a second capacitor which stores a second data independent from said first data;
a first circuit connected to said first capacitor;
a first compare line to which a first comparative data is input;
a second circuit connected to said first compare line and connected in series with said first circuit;
a third circuit connected to said second capacitor;
a second compare line to which a second comparative data is input; and
a fourth circuit connected to said second compare line and connected in series with said third circuit; and
a match line to which said second circuit and said third circuit are connected,
wherein said first circuit and said fourth circuit are grounded.

19. The semiconductor storage device as set forth in claim 18,wherein said first to fourth circuits are designed to electrically connect said match line and said ground line either when said first data stored in said first capacitor and a first comparative data input to said first compare line are detected to be identical, or when said second data stored in said second capacitor and a second comparative data input to said second compare line are detected to be identical.

20. The semiconductor storage device as set forth in claim 10, wherein said first comparative data and said second comparative data are mutually complementary.

21. The semiconductor storage device as set forth in claim 18, wherein said first comparative data and said second comparative data are mutually complementary.

22. The semiconductor storage device as set forth in claim 1, is formed as an embedded DRAM.

23. The semiconductor storage device as set forth in claim 2, is formed as an embedded DRAM.

24. The semiconductor storage device as set forth in claim 11, is formed as an embedded DRAM.

25. The semiconductor storage device as set forth in claim 16, is formed as an embedded DRAM.

26. The semiconductor storage device as set forth in claim 18, is formed as an embedded DRAM.
